(19) United States
(12) Patent Application Publication
(10) Pub. No.: US 2008/0203902 A1
(43) Pub. Date: Aug. 28, 2008

(54) Oled-Device with Patterned Layer Thickness

(75) Inventors: Margreet De Kok, Eindhoven (NL); Eric Alexander Meulenkamp, Eindhoven (NL)

Correspondence Address: PHILIPS INTELLECTUAL PROPERTY & STANDARDS, PO BOX 3001, BRIARCLIFF MANOR, NY, 10510-8001, US

(73) Assignee: KONINKLIJKE PHILIPS ELECTRONICS N.V., EINDHOVEN (NL)

(21) Appl. No.: 11/816,328

(22) PCT Filed: Feb. 9, 2006
(86) PCT No.: PCT/IB06/50429

§ 371 Date: Aug. 15, 2007

(30) Foreign Application Priority Data
Feb. 17, 2005 (EP) 05101172.4

(51) Int. Cl. H01L 51/50; H01L 51/00

(52) U.S. Cl. 313/504; 313/498

(57) ABSTRACT

A light emitting device comprising a substrate (1) supporting a plurality of layers (2, 3, 5), of which two sandwich a light emitting layer (4), said device being patterned into a plurality of independently addressable domains (11, 12) is disclosed. At least one of said layers (2, 3, 5) is of a first thickness in said first domain and of a second thickness in said second domain, such that when a voltage, that is sufficient to cause light to emit from said light emitting layer (4), is applied over said light emitting layer, light of a first color point is emitted by said first domain (11) of said device and light of a second color point is emitted by said second domain (12) of said device.

### TECHNICAL FIELD

The present invention relates to a light emitting device comprising a substrate supporting a plurality of layers of which two sandwich a light emitting layer, said device being patterned into a plurality of independently addressable domains.

### TECHNICAL BACKGROUND

Organic based light emitting diodes (OLEDs), such as polymer OLEDs (polyLEDs), small-molecule OLEDs (smOLEDs) and light emitting electrochemical cells (LEEC) are proposed for several different lighting applications, such as for providing ambient light and as light sources in flat panel displays.

The technology of organic LEDs allows for the fabrication of for instance, thin, self-emissive displays, based on light emitting materials. These materials may be for example small-molecules, dendrimers, oligomers, and polymers.

Organic LEDs typically consist of a multi-layer structure, with one or more layers with electrical and/or optical functionality sandwiched between two conductive electrodes. Standard ITO may be used for the anode, and the cathode is specially designed to facilitate the electron injection. At least one of the layers is an active layer responsible for light emission. Other layers may be present to enhance the organic LED performance. For example, insertion of hole and/or electron injection and transport layer(s) is known to result in improved performance of several types of organic LEDs.

Thus, a typical OLED comprises two organic layers sandwiched between two conductive electrodes. Counting from the anode, the first of the organic layers is responsible for hole transport and the second layer is responsible for the light generation. Electrons injected by the cathode and holes injected from the anode recombine in the light-emitting layer, resulting in an exciton that decays radiatively in producing a photon. The color of the emitted light may thus be tuned by varying the band-gap of the emissive material used.

For lighting applications, the color-tunability, i.e. the ability to tune the color point (temperature) to a desired value, of a white light source is a very important feature. The wider the color points may be chosen by the consumer, the better equipped the light source is. “Emotional lighting” in which atmosphere may be created by a different color temperature of the artificial light is regarded as an important feature for future light sources.

One common approach to obtain a color-tunable organic LED light source is to combine differently colored pixels into one device by pixelating different light emitting materials, as is usually done in a full-color display. However, such an approach requires the use of more than one light emitting material, and is as such cumbersome to manufacture.

A device that allows a user to choose the color temperature of light emitted by a polyLED, utilizing a single light emitting material, is described in U.S. Pat. No. 6,091,197, to Sun et al.

In this patent, Sun et al describe a color-tunable organic light emitting diode (RCOLED) including a high-reflection tunable membrane and a high-reflection dielectric mirror that form a resonant cavity. A white-light OLED is located in the resonant cavity. The high-reflection tunable membrane is moved to alter the resonant cavity length, and/or tilted/bowed to change the finesse of the resonant cavity. In this way, color, brightness and color saturation of the emitted light from the RCOLED may be tuned. This device is quite complicated to produce, and for color tuning it requires mechanical influences on the device, e.g. by moving, tilting and/or bowing the reflection membrane.

Thus, there remains a need for color-tunable light emitting devices which obviate the need for several different light emitting materials, and which not require mechanical influences on the device for the color tuning.

### SUMMARY OF THE INVENTION

One object of the present invention is to overcome the above-mentioned problems with prior art.

The inventors have surprisingly found that the color point, e.g. as defined by a certain coordinate in for example a color rendering index diagram, of light emitted by an OLED-device depends on the thickness of any layer in the device that affects the optical cavity and thus the out-coupling of light.

By providing a patterned OLED-device having a layer that is patterned in thickness into several domains, and which domains are driven individually, a color-tunable device is obtainable. A color-tunable device, as used herein, refers to a light-emitting device with a possibility of controlling the color point of emitted light, e.g. either automatically by a feedback system or manually by a user. Thus, in a first aspect, the invention provides a light-emitting device based on OLED-technology where different domains of the device emit light with different color points.

Such a device comprises a substrate supporting a plurality of layers of which two sandwich a light emitting layer comprising an organic electro luminescent compound, said device being patterned into a plurality of independently addressable domains.

In a device of the present invention, at least one of the layers is of a first thickness in a first domain and of a second thickness in a second domain. Due to this difference in thickness, light of a first color point is emitted by the first domain of said device and light of a second color point is emitted by the second domain of said device, when a voltage, that is sufficient to cause the light emitting layer to emit light, is applied.

By driving each of these portions independently, the color point of light emitted from a device of the invention may be tailored by mixing light from different portions of different color points to obtain a color variable light-emitting device.

Thus, a color variable light emitting OLED-device may be obtained by using only one light emitting layer material. Layers other than the light emitting layer, that are typically comprised in an OLED-device, and which consequently may be of a first thickness in a first domain and of a second thickness in a second domain includes an anode and a cathode. Other layers, such as a buffer layer having hole transporting and/or injecting functionality being arranged between the anode and the light emitting layer or a buffer layer having electron transporting and/or injecting functionality being arranged between the light emitting layer and the cathode may also have a first thickness in a first domain of the device and a second thickness in a second domain of the device.

One or more of such layers may be of a first thickness in a first domain and of a second thickness in a second domain of a device according to the present invention in order to obtain a device according to the present invention.

Suitable materials for the anode, cathode, hole injecting and transporting layer and electron injecting and transporting layer are known to those skilled in the art. In embodiments of the invention, the light-emitting layer may comprise organic electro luminescent compounds (emitters), such as, for example small organic molecule emitters, oligomeric emitters, polymeric emitters or dendrimeric emitters.

The light emitting material may further comprise a blend or mixture of two or more different emitters, for example two emitters of different type and/or emitters that emit light of different colors. A device of the present invention may provide white light. Especially, the first color point corresponding to a first domain of the device may represent a first white color point and a second color point corresponding to a second domain of the device may represent a second white color point. Thus, all possible combinations of driving a multi-domain device of the present invention yield a white light. Light emitting devices according to the present invention may for example be used in different lighting systems, for example room lighting, stage lighting, and for backlight applications in display devices, such as LCD-displays.

### BRIEF DESCRIPTION OF THE DRAWINGS

The present invention will now be further described in the following description of preferred embodiments with reference to the drawings, in which:

FIG. 1 illustrates, in cross section, a light-emitting device of the present invention with a patterned PEDOT:PSS layer.

FIG. 2 is a graph of the electro luminescence spectra of devices having a 80 nm thick light emitting polymer layer and varying PEDOT:PSS layer thickness of 50 nm, 100 nm and 200 nm.

FIG. 3 is a color coordinate diagram of devices having a 80 nm thick light emitting polymer layer and varying PEDOT:PSS layer thickness of 50 nm, 100 nm and 200 nm.

### DETAILED DESCRIPTION OF PREFERRED EMBODIMENTS

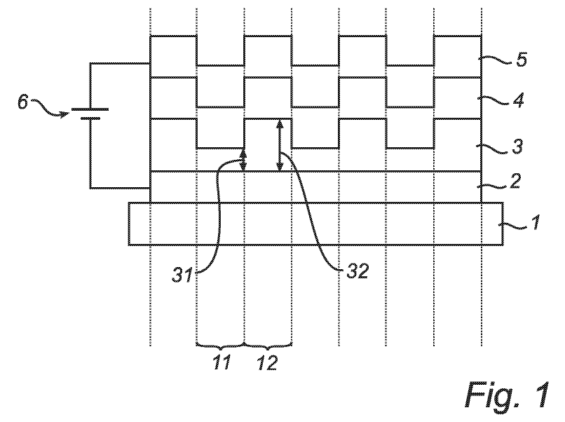

One embodiment of the present invention is shown in FIG. 1 and comprises a substrate 1, an anode 2 arranged on the substrate 1, a hole transporting buffer layer 3 arranged on the anode 2, a light emitting polymer (LEP) layer 4 arranged on the hole transporting buffer layer 3 and a cathode 5 arranged on the LEP-layer 4.

The hole-transporting buffer layer 3 is of a first thickness 31 in a first domain 11 and of a second thickness 32 in a second domain 12.

The anode 2 and the cathode 5 are connected to a LED-driving unit 6, which drives the anode and the cathode such that domains of the device, corresponding to different domains of the patterned hole-transporting buffer layer 3, may be driven independently to emit light. The patterning of the hole-transporting buffer layer 3 into domains and the independent driving of those domains gives that the device is patterned into a plurality of different domains 11, 12.

When driven at the same voltage, the different domains 11, 12 of the device emit light of different color-points, and thus, by driving the different domains independently, the total color emitted by the device may be tuned in a range defined by the different color-points for the individual domains of the device.

As used herein, the term “color-point” refers to a certain coordinate in a chromaticity diagram, for example a (x,y)-coordinate in the 1931 CIE standard diagram or (u′,v′)-coordinate in the 1976 CIE standard diagram.

As used herein, the term “white” light refers to light having a color point inside the area of “white” light as defined in for example the 1931 or 1976 CIE standard diagram.

As used herein, the term “OLED” refers to all light emitting diodes (LEDs) based on organic electro luminescent compounds, such as light emitting materials based on small organic molecules (smOLED), polymers (polyLED), oligomers and dendrimers. Examples of suitable substrates include, but are not limited to glass, transparent ceramics and transparent plastic substrates. Plastic substrates are attractive alternatives to glass and ceramics when suitable, because they are lightweight, inexpensive and flexible, among other advantages. The anode 2 is arranged on the substrate and may be of any suitable material known to those skilled in the art, such as indium tin oxide (ITO).

Typically, the light emitted by the light emitting polymer layer leaves the device via the anode side, where the color is tuned through the thickness of the hole-transporting layer. Thus, the anode is preferably transparent or translucent.

In a second preferred embodiment of the invention, the anode 2 is of a first thickness in a first domain and of a second thickness in a second domain, in order to provide the color tunability of a device according to the present invention. A hole-transporting buffer layer 3 is arranged on the anode 2 to transport holes (positive charges) towards and injecting holes into the light-emitting layer 4 under the influence of an electric field applied between the anode 2 and the cathode 5.

Suitable hole transporting and injecting buffer layer materials for use in the present invention include, but are not limited to PEDOT:PSS (polyethylenedioxythiophene polystyrenesulfonate salt) and PANI (polyaniline). Other hole-transporting buffer materials, suitable for use in a device of the present invention, are known to those skilled in the art.

As shown in FIG. 1, the hole-transporting buffer layer 3 is patterned in thickness to domains having a first thickness 31 and domains having a second thickness 32. It will be obvious to those skilled in the art that the hole transporting buffer layer may be patterned in thickness to domains of more than two, e.g. three or four, different thicknesses.

A number of techniques for forming the hole-transporting buffer layer with patterned thickness are possible. For example, the hole-transporting buffer layer may be deposited by ink-jet printing of the material on the anode layer, to control the amount of material deposited in, and thus the thickness of the material of a specific area representing a domain. Another suitable technique includes spin-coating of the buffer layer material followed by patterned curing of the material, such as by UV-radiation through a mask, and rinsing off uncured material, as is shown, for example, in WO 01/020691 and WO 03/067333.

Preferably, essentially the same material is used in all the domains of the patterned hole-transport buffer layer.

The hole transporting buffer layer may independently vary in thickness in the different domains, and the thickness may be in the range of 5 and 500 nm, preferably between 10 and 300 nm.

The hole transporting and injecting buffer layer is optional for the functionality of the device. Consequently, it may or may not be comprised in a device of the present invention. However, it is conventionally used as it improves the functionality of commonly used OLED-devices.

A device of the present invention may comprise an electron transporting and injecting buffer layer being arranged between the cathode 5 and the light emitting layer 4, as such layers may improve the functionality of the device.

Further, such an electron transporting and injecting buffer layer may be of a first thickness in a first domain and of a second thickness in a second domain, as described above for the hole injecting and transporting layer, in order to provide the color tunability of a device according to the present invention.

Examples of suitable materials having electron injecting and/or transporting functionality includes, but are not limited to TPBI: 2,2′,2″-(1,3,5-benzenetriyl)tris[1-phenyl-1H-benzimidazole], DCP: 2,9 dimethyl-4,7-diphenyl-phenantroline, TAZ: 3-phenyl-4-(1′naphtyl)-5-phenyl-1,2,4-triazole and OXD7: 1,3-bis(N,N-t-butyl-phenyl)-1,3,4-oxadiazole. More examples of such materials are described in Adv. Mater. 16 (2004) 1585-1595 and Appl. Phys. Lett. (2002) 1738-1740.

A device of the present invention may also comprise other additional layers with optical and/or electrical functionality, as is known to those skilled in the art. The light-emitting layer may comprise any organic electro luminescent light emitting compound or any combinations of such compounds known to those skilled in the art. Light of virtually every color is possible to achieve by such organic electro luminescent compounds. Examples of organic electro luminescent compounds include electro luminescent small organic molecules, oligomers, polymers and dendrimers.

Examples include, but are not limited to Alq3: tris(8-hydroxy-quinoline)aluminum and Ir(py)3: tris(2-phenylpyridine)iridium. More examples are described in for example Adv. Mater. 16 (2004) 1585-1595 and Appl. Phys. Lett. (2002) 1738-1740.

Conventional electro luminescent polymers include organic material such as derivatives of poly(p-phenylene vinylene) (PPV) or polyfluorenes and poly(spiro-fluorenes). Other electro luminescent polymers are well known to those skilled in the art.

Any electro luminescent polymer or combination of such polymers may be used in a light emitting polymer layer of the present invention to obtain any desired color. For example, essentially white light may be obtained by a blended combination of a blue-emitting polymer and a red-emitting polymer. One example of such a combination will be described in the following examples. Other combinations of light emitting polymers for providing light of different colors are known to those skilled in the art, as well as single component polymers incorporating different dye monomers on one polymer chain.

The light emitting layer may have any thickness at which the light emitting layer is capable of emitting light under the influence of an electrical field, and will be different for different types of devices, where the minimum thickness in some smOLED devices is of the order of 10 nm, and the maximum in LEEC-devices in of the order of 500 nm.

The light-emitting layer may be arranged on the buffer layer by any suitable method, including, amongst others, spin-coating, spraying or printing like ink-jet, screen or gravure printing.

The present invention also relates to other light emitting materials based on organic electro luminescent compounds, such as electro luminescent small organic molecules, oligomers and dendrimers. As will be apparent to those skilled in the art, also different combinations of such organic electro luminescent compounds may be useful in a device of the present invention.

The above description relates to a single light-emitting layer. However, in some embodiments the light-emitting layer may comprise more than one, such as for example two or three, separate sub-layers arranged on top of each other. For example, a blue-emitting layer may be arranged on top of an orange-emitting layer in order to provide white light. The cathode is arranged on the light-emitting layer, optionally with an additional layer, such as an electron injecting and transporting layer, being sandwiched between the cathode and the light-emitting layer. Several cathode materials are well known to those skilled in the art, and all of them are contemplated as suitable. Examples of suitable cathode materials include calcium, magnesium and aluminum.

Typically, a device of the present invention is arranged such that light emitted by the light emitting layer leaves the device via the anode, through the substrate. However, in some embodiments of the present invention, light may also leave the device via the cathode layer. Thus, in such embodiments, the cathode may be formed by a material that is transparent or translucent to the emitted light.

In one embodiment of the present invention, the cathode 5 is of a first thickness in a first domain of the device and of a second thickness in a second domain of the device, in order to provide the color tunability of a device according to the present invention. As will be shown in the following example, the color point of light emitted by the device depends on the thickness of the hole transporting buffer layer.

Not wishing to be bound by any specific theory, two effects may account for this change of the color points.

A thicker buffer layer leads to a lower current density as compared to thinner layers at comparable voltages. This may imply that the charge balance in the device changes and that the recombination zone shifts. The out-coupling of the light will therefore be changed, leading to color point variation.

A second effect is also related to out-coupling, but occurs independently from any change in electrical characteristics of the device. The wavelength dependent out-coupling of light from the polyLED depends on the thickness of all layers close to the light-emitting layer. Thus, variation of the PEDOT thickness causes a different out-coupling, and thereby a different color. Since this mechanism of color tuning is independent from the electrical device characteristics, different color points may be obtained at the same luminance by PEDOT thickness variation. In a device of the present invention, the anode and the cathode are arranged such that different portions of the device, corresponding to different domains of the patterned buffer layer, are driven independently.

As used herein “independently addressable domains” refers to that a domain is possible to drive, i.e. it is possible to apply an electrical field over a domain, irrespective of the driving of an adjacent domain.

It will be apparent to those skilled in the art how to arrange the anode and the cathode layers in order to obtain a domain-specific driving, and both active and passive driving of a device of the present invention may be suitable.

Thus, the color point of the total light emitted by a device of the present invention may be varied by mixing light from different portions of the device having different individual color points.

The above description of preferred embodiments are illustrative only, and modifications to and variants of these embodiments will be apparent to those skilled in the art. Such modifications and variants are also included within the scope of the appended claims. For example, in some embodiments also the anode and/or the cathode may be patterned in thickness as described above for the patterned buffer layer, in order to provide a color-tunable light-emitting device.

Further, it has been shown that the color point of light emitted by a device of the present invention is dependent of the voltage that drives the device. This effect could be combined with the color-effect of varying the thickness of layer, as described above, to obtain a color variable light-emitting device.

In one embodiment of the present invention, the plurality of independently addressable domains are arranged on a single substrate, forming a single multi-domain LED-device.

In another embodiment of the present invention the different independently addressable domains are arranged on separate substrates, forming a multi-LED-device.

The present invention will now be further described by the following non-limiting example.

### Example

### Different PEDOT-Layer Thicknesses Lead to Different Color Points

Three polyLEDs were manufactured, which were identical except for the PEDOT-layer thickness, which were 50 nm, 100 nm and 200 nm thick respectively. An 80 nm thick layer of light emitting polymer was used. The light emitting polymer consisted of a mixture of 99% of blue light emitting polymer (blue 1, formula I) and 1% of a red emitting polymer (NRS-PPV, formula II).

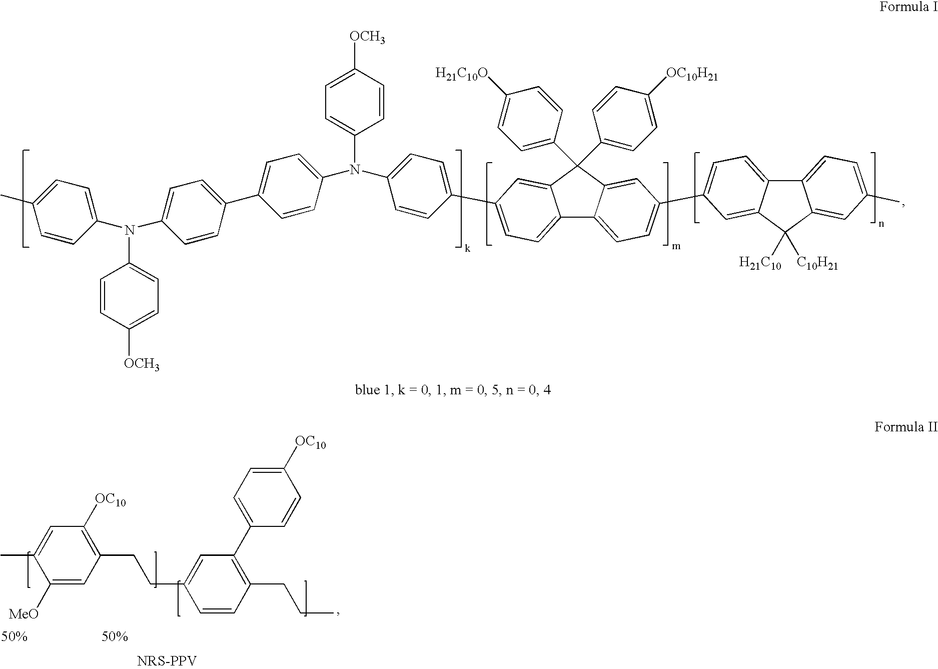

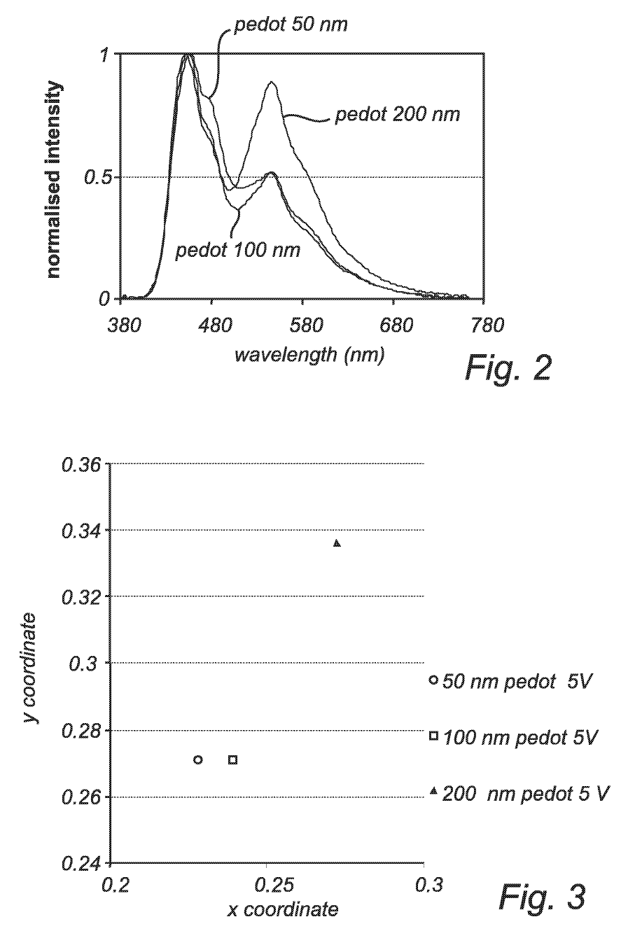

The spectra from the three different devices were compared at a bias of 5 Volts, and the results show clearly that an increase in PEDOT-layer thickness leads to an increase in x- and y-coordinate (FIGS. 2 and 3).

This example clearly shows color point variation as a function of the PEDOT-layer thickness. The color temperatures available with these three pixels are all around 10000 K. However, using other electro luminescent compounds, or other thicknesses of the PEDOT-layer, other color temperatures may also be available.

It will be clear that meaningful variation of the color point may be achieved in an interesting luminance range.

The thickness range used is of practical use. Thus, the efficiency does not drop to very low values, which would lead to high power consumption, and the voltage required is not extreme.

A practical implementation would be to have three types of pixels with the thickness shown in the graphs. By appropriate driving all colors between the extremes in FIG. 3 may then be generated. For example, 100 nit (cd/m²) (0.23;0.27) would need 300 nit driving of the 50 nm PEDOT pixel, in case of equal surface area of each thickness.

White, or essentially white light may be advantageously emitted by a device of the present invention in several applications. However, the present invention is in no way limited to devices emitting white light, and devices providing tunable light of other colors may also be obtained, for example by utilizing electro luminescent compounds producing light of other colors.

1. A light emitting device comprising a substrate supporting a plurality of layers, of which two sandwich a light emitting layer, said device being patterned into a plurality of independently addressable domains characterized by that
at least one of said layers is of a first thickness in a first domain and of a second thickness in a second domain, such that when a voltage, that is sufficient to cause light to emit from said light emitting layer, is applied over said light emitting layer, light of a first color point is emitted by said first domain of said device and light of a second color point is emitted by said second domain of said device.

2. A device according to claim 1, wherein said layer having a first thickness in a first domain of said device and a second thickness in a second domain of said device is an anode layer.

3. A device according to claim 1, wherein said layer having a first thickness in a first domain of said device and a second thickness in a second domain of said device is a cathode layer.

4. A device according to claim 1, wherein said layer having a first thickness in a first domain of said device and a second thickness in a second domain of said device is a layer having hole injecting and/or transporting functionality.

5. A device according to claim 1, wherein said layer having a first thickness in a first domain of said device and a second thickness in a second domain of said device is a layer having electron injecting and/or transporting functionality.

6. A device according to claim 1, wherein said light emitting layer comprises at least a first organic electro luminescent compound.

7. A device according to claim 6, wherein said light emitting layer comprises at least a first organic electro luminescent compound and a second organic electro luminescent compound.

8. A device according to claim 7, wherein said first color point represents a first white color point and said second color point represents a second white color point.

9. A lighting system comprising a light-emitting device according to claim 1.

10. A display device comprising a light-emitting device according to claim 1.
